(19) United States
(12) Patent Application Publication
(10) Pub. No.: US 2008/0094801 A1
(43) Pub. Date: Apr. 24, 2008

(54) HEAT DISSIPATION MODULE

(75) Inventors: Yen-Yang Lien, Taipei (TW); Ching Ho, Taipei (TW); Yueh-Lung Chuang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: AMA PRECISION INC., Taipei (TW)

(21) Appl. No.: 11/874,921

(22) Filed: Oct. 19, 2007

(30) Foreign Application Priority Data
Oct. 19, 2006 (TW) 95138534

(51) Int. Cl. H05K 7/20

(52) U.S. Cl. 361/704

(57) ABSTRACT

A heat dissipation module is suitable to dissipate heat for a heat source on a circuit board, wherein a plurality of locking holes are disposed around the heat source. The heat dissipation module includes a heat sink, a locking rod, and two fasteners. The heat sink has a groove, and the locking rod has a rod body and two hooks extended from two ends of the rod body. The rod body is across the groove. In addition, each fastener is connected to each corresponding hook, and is fastened at the locking hole.

### CROSS-REFERENCE TO RELATED APPLICATION

This application claims the priority benefit of Taiwan application serial no. 95138534, filed on Oct. 19, 2006. All disclosure of the Taiwan application is incorporated herein by reference.

### BACKGROUND OF THE INVENTION

1. Field of the Invention

The invention relates to a heat dissipation module and, more particularly, to a heat dissipation module with a locking rod and fasteners simultaneously.

2. Description of the Related Art

In recent years, with the rapid development of the science and technology, the heat dissipation power of an electronic device, such as that in a computer, is continuously increased along with the continuous promotion of the operation speed of the electronic device. In order to protect the electronic device against the temporary or permanent failure because of the overheating of the electronic device within the computer, the electronic device needs sufficient heat dissipation ability to ensure its normal operation.

FIG. 1A is a schematic diagram showing a conventional heat dissipation module assembled on a circuit board, while FIG. 1B is an exploded diagram showing the heat dissipation module and circuit board showed in FIG. 1A. Please refer to FIG. 1A and FIG. 1B simultaneously. The conventional heat dissipation module 100 is mainly composed of a heat sink 110 and a plurality of push pins 120. The heat dissipation module 110 can be assembled on the heat source 12 on the circuit board 10 by the push pins 120, wherein the heat source 12, for example, is a heat generating chip on the circuit board 10. In the conventional technology, the heat sink 110 includes a group of fins 112 and two fixed parts 114. The group of fins 112 and two fixed parts 114 are integrally formed, and the two fixed parts 114 are provided on the corresponding sides of the group of fins 112, respectively. Moreover, a plurality of locking holes 10a are provided in the circuit board 10 and around the heat source 12. In the conventional technology, the push pins 120 pass through the holes 114a of the fixed part 114, and are fastened at the locking holes 10a. Thus, the heat sink 110 can be assembled on the heat source 12 steadily to dissipate the heat for heat source 12.

However, the extra provided fixed part 114 increases the material cost of the heat sink 110, and the material of the fixed part is expensive metal such as copper and aluminum, so the conventional heat dissipation module has a higher product cost.

### BRIEF SUMMARY OF THE INVENTION

An objective of this invention is to provide a heat dissipation module with a low product cost.

To achieve the above or other objectives, the invention provides a heat dissipation module which is suitable to dissipate heat of a heat source on a circuit board, wherein a plurality of locking holes are disposed around the heat source. The heat dissipation module mainly includes a heat sink, a locking rod and two fasteners. The heat sink has a groove, and the locking rod has a rod body and two hooks extended from two ends of the rod body. The rod body is across the groove. In addition, each fastener is connected to its corresponding hook and fastened at the locking holes.

In an embodiment of this invention, each hook has a limiting space passed through by its corresponding fastener.

In an embodiment of this invention, each fastener has a top interfering with the hook, a fastener body within the limiting space, and a fastener part fastened at the locking hole.

In an embodiment of this invention, each fastener has a hole passed through by the hook.

In an embodiment of this invention, each fastener has a top, a fastener body and a fastener part, wherein the hole is provided at the fastener body, and the fastener part is fastened at the locking hole.

In an embodiment of this invention, each fastener has a fastener body and a fastener part, wherein the fastener part is connected to the fastener body.

In an embodiment of this invention, the fasteners are plastic pins.

In an embodiment of this invention, the heat dissipation module further includes a fixed element provided in the groove, while the central section of the rod body is held in the fixed element.

In the embodiment of the invention, some parts of the rod body press the heat sink.

In an embodiment of the invention, the heat sink is a group of fins.

In an embodiment of this invention, the group of fins includes a plurality of aluminum extrusion fins.

The combination of the locking rod and the fasteners of the heat dissipation module of this invention can fix the heat sink to the circuit board directly. In other words, an extra fixed part is not needed to be provided on the side of the heat sink. Therefore, the heat sink has a lower material cost, and the heat dissipation module has a lower product cost.

These and other features, aspects, and advantages of the invention will become better understood with regard to the following description, appended claims, and accompanying drawings.

### BRIEF DESCRIPTION OF THE DRAWING

FIG. 1A is a schematic diagram showing a conventional heat dissipation module assembled on the circuit board.

FIG. 1B is an exploded diagram showing the heat dissipation module and circuit board shown in FIG. 1A.

FIG. 2A is a schematic diagram showing a heat dissipation module in a preferred embodiment of this invention assembled on a circuit board.

FIG. 2B is an exploded diagram showing the heat dissipation module and circuit board shown in FIG. 2A.

FIG. 3A is a schematic diagram showing another heat dissipation module in a preferred embodiment of this invention assembled on a circuit board.

FIG. 3B is an exploded diagram showing the heat dissipation module and circuit board shown in FIG. 3A.

FIG. 4 is an assembled diagram showing the heat dissipation module shown in FIG. 3A and the circuit board with another form.

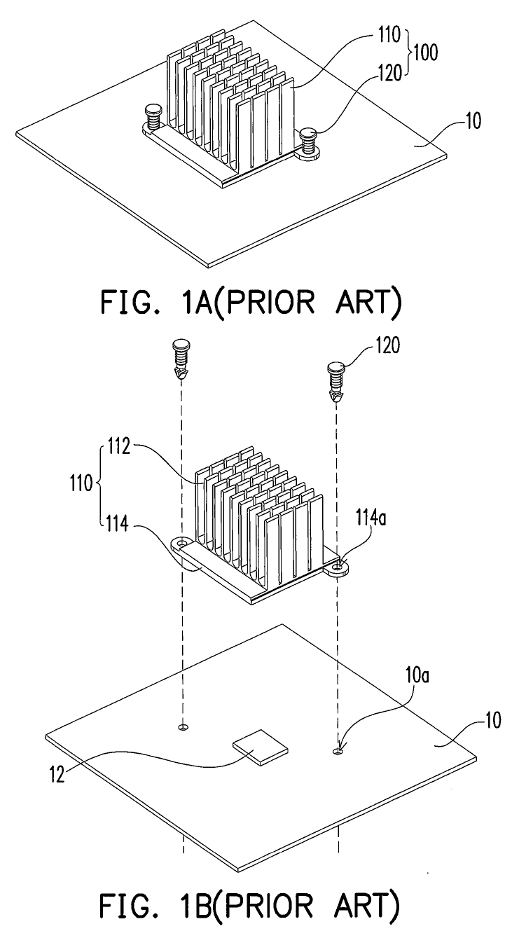

### DETAILED DESCRIPTION OF THE EMBODIMENTS

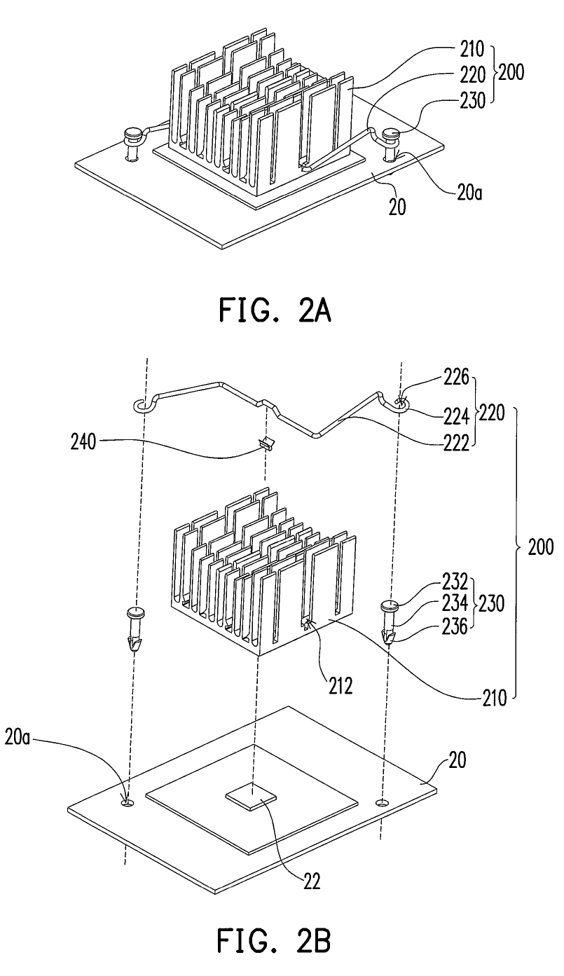

FIG. 2A is a schematic diagram showing a heat dissipation module of a preferred embodiment of this invention assembled on the circuit board, while FIG. 2B is an exploded diagram showing the heat dissipation module and the circuit board shown in FIG. 2A. Please refer to FIG. 2A and FIG. 2B simultaneously. The heat dissipation module 200 in this embodiment is suitable to be provided on the heat source 22 on the circuit board 20 to dissipate the heat generated by the heat source 22, wherein the circuit board 20 is, for example, a motherboard, and the heat source 22 is, for example, a north bridge chip or other heat generating chip on a motherboard. The heat dissipation module 200 of this embodiment includes a heat sink 210, a locking rod 220 and two fasteners 230, and the heat sink 210 can be fixed on the heat source 22 by the combination of the fasteners 230 and locking rod 220. In this embodiment, a plurality of locking holes 20a are provided around the heat source 22 on the circuit board 20, while the fasteners 230 connected to the locking rod 220 are fastened at the locking holes 20a so that the heat sink, for example, which is the group of fins 210 can be fixed on the heat source 22, wherein the group of fins, for example, is composed of a plurality of aluminum extrusion fins, and the locking rod 220, for example, is a metal rod with a characteristic of elastic deformability, while the fasteners 230 may be plastic pins. How the heat sink 210 can be fixed on the heat source 22 by the combination of the fasteners 230 and the locking rod 220 will be described hereinbelow in detail.

Please continue to refer to FIG. 2A and FIG. 2B. In this embodiment, the heat sink 210 has a groove 212. The locking rod 220 includes a rod body 222 and two hooks 224, wherein the rod body 222 is across the groove 212, while the hooks 224 are extended from two ends of the rod body 222 respectively. The two ends of the above rod body 222, for example, are bent semicircularly to form hooks 224, while the fasteners 230 pass through the limiting space 226 of the hooks 224 to interfere with the locking rod 220. More specifically, the fastener 230 is composed of a top 232, a fastener body 234 and a fastener part 236, wherein the top 232, for example, interferes with hooks 224, and the fastener body 234 is within the limiting space 226. Herein, the bending degree of the hooks 224 is not be limited, and the hooks which can interfere with the fasteners 230 are all within the spirit and scope of this invention.

From the above, since the fasteners 230 are connected to the hooks 224, users can force on the fasteners 230 to make the fastener parts 236 of the fasteners 230 be fastened at the locking holes 20a of the circuit board 20. More specifically, when the users force on two fasteners 230 which are connected to the locking rod 220, the locking rod 220 is deformed because it bears two opposite torque so that two fasteners 230 can be fastened at the locking holes 20a successfully. At the same time, the locking rod 220 (rod body 222) bearing the torque presses the base of the heat sink 210. Thus, the heat sink 210 can press the heat source 22 tightly by the combination of the locking rod 220 and fasteners 230 to dissipate the heat generated by the heat source 22.

On the other hand, to make the rod body 222 across the groove 212 steadily, a fixed element 240 can be provided in the groove 212 in this embodiment, while the central section of the rod body 222 can be held in the fixed element 240.

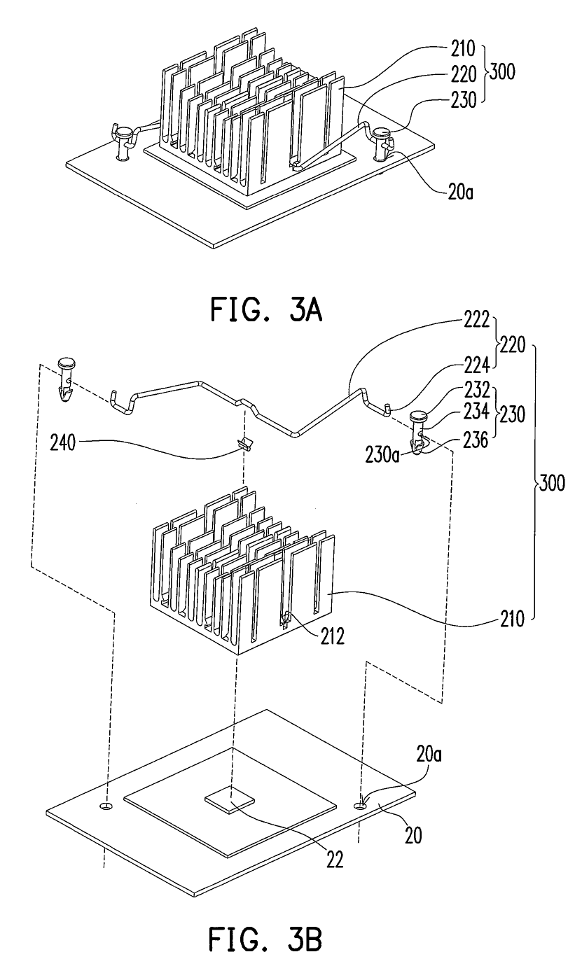

In addition, the heat dissipation module shown in FIG. 2A and FIG. 2B is not an only embodiment of this invention. Other embodiments of the invention will be described hereinbelow. To make the description more concise, the same reference numbers are used to denote the same parts in the description hereinbelow. FIG. 3A is a schematic diagram showing another heat dissipation module of the preferred embodiment of the invention assembled on the circuit board, while FIG. 3B is an exploded diagram showing the heat dissipation module and the circuit board shown in FIG. 3A. Please refer to FIG. 3A and FIG. 3B simultaneously, the heat dissipation module 300 of this embodiment is similar to the heat dissipation module 200 of the previous embodiment. The main difference between them is that the fastener 230 of this embodiment has a hole 230a, and the hook 224 passes through the hole 230a, wherein the hole 230a, for example, is provided in the fastener body 234. In this embodiment, users only need to fasten the fastener parts 236 of the fasteners 230 in the locking holes 20a of the circuit board 20, and then locking rod 220 (rod body 222) presses the base of the heat sink 210 so that the heat sink 210 presses the heat source 22 tightly. In other words, the heat sink 210 in this embodiment also can be fixed on the heat source 22 steadily by the combination of the locking rod 220 and the fasteners 230.

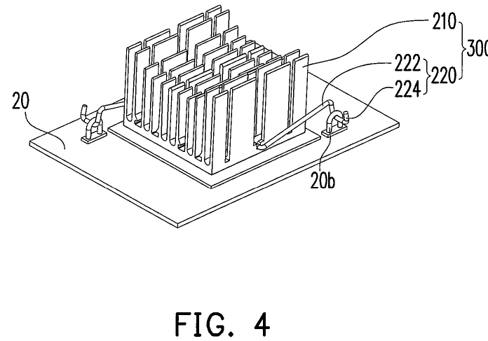

When the locking holes 20a provided on the circuit board 20 are replaced with the rings 20b (Please refer to FIG. 4 which is an assembled diagram showing the heat dissipation module shown in FIG. 3A and a circuit board in another form.), users only need to take off the fasteners 230 (shown in FIG. 3A) of the heat dissipation module 300, and fasten the hooks 224 into the rings 20b, and then, the heat sink 210 is also fixed on the heat source. That is to say, the heat dissipation module 300 of this embodiment has a preferred structure compatibility.

To sum up, the combination of the locking rod and fasteners of the heat dissipation module of this invention can make the heat sink assembled on the heat source on the circuit board directly. Compared with the conventional technology which needs an extra fixed part provided on the sides of the group of the fins, the heat sink of this invention has a lower material cost. In other words, the heat dissipation module of this invention has a lower product cost. In addition, since the heat dissipation module of this invention has the locking rod and fasteners simultaneously, no matter which are provided around the heat source, locking holes or rings, the heat sink of this invention can be assembled on the heat source steadily to dissipate the heat for heat source. That is, the heat dissipation module of this invention has a preferred structure compatibility.

Although the invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat dissipation module suitable to dissipate heat generated by a heat source on a circuit board, wherein a plurality of locking holes are provided around the heat source, the heat dissipation module comprising:
a heat sink having a groove;
a locking rod which has a rod body across the groove and two hooks extended from two ends of the rod body, respectively; and,
two fasteners connected to the hooks and fastened at the locking holes.

2. The heat dissipation module according to claim 1, wherein each of the hooks has a limiting space, and the fastener passes through the limiting space.

3. The heat dissipation module according to claim 2, wherein each of the fasteners has a top, a fastener body and a fastener part, and the top interferes with the hook, and the fastener body is within the limiting space, while the fastener part is fastened at the locking hole.

4. The heat dissipation module according to claim 1, wherein each of the fasteners has a hole, and the hook passes through the hole.

5. The heat dissipation module according to claim 4, wherein each of the fasteners has a top, a fastener body and a fastener part, and the hole is provided at the fastener body, while the fastener part is fastened at the locking hole.

6. The heat dissipation module according to claim 1, wherein the fasteners are plastic pins.

7. The heat dissipation module according to claim 1, further comprising a fixed element, the fixed element provided in the groove, and the central section of the rod body held in the fixed element.

8. The heat dissipation module according to claim 1, wherein the heat sink has a group of fins.

9. The heat dissipation module according to claim 8, wherein the group of fins comprises a plurality of aluminum extrusion fins.
